(19) United States
(12) Patent Application Publication
(10) Pub. No.: US 2024/0363661 A1
(43) Pub. Date: Oct. 31, 2024

(54) OPTICAL PIXEL WITH AN OPTICAL CONCENTRATOR AND A FULL-DEPTH DEEP ISOLATION TRENCH FOR IMPROVED LOW-LIGHT PERFORMANCE

(71) Applicant: SiOnyx, LLC, Beverly, MA (US)

(72) Inventor: Jutao JIANG, Tigard, OR (US)

(73) Assignee: SiOnyx, LLC, Beverly, MA (US)

(21) Appl. No.: 18/307,388

(22) Filed: Apr. 26, 2023

(51) Int. Cl. H01L 27/146; G02B 3/00; G02B 3/08; G02B 5/18

(52) U.S. Cl. CPC H01L 27/1463; G02B 3/0037; G02B 3/08; G02B 5/1842; H01L 27/14621; H01L 27/14625; H01L 27/14627; H01L 27/14629; H01L 27/14685

(57) ABSTRACT

A new pixel architecture that enables a reduced dark current and improved signal-to-noise. A light-sensing pixel is configured to have a large optical acceptance aperture, a light concentration structure, and a pixel-sensing area smaller than the optical acceptance aperture, which allows for the collection of more photons without increasing dark current or read noise in the smaller pixel-sensing area. The pixel sensing area may be bordered by a deep trench isolation boundary, which combined with the smaller sensing area, can significantly improve night vision technology, making it more efficient and effective. Certain implementations may also include a metal-filled deep trench isolation boundary around each pixel to eliminate pixel-to-pixel crosstalk.

### FIELD

The disclosed technology generally relates to imaging applications and image sensor technologies, and in particular to pixel architectures that utilize a light concentrator to reduce dark current.

### BACKGROUND

Light concentrators can be used in various applications, including solar power generation, camera lens design, etc., to enable the efficient harvesting of available light. For camera lens design, light concentrators can help to reduce the exposure time required to create clearer images by directing light onto the camera's sensor.

For night vision, analog image intensification (I2) tube devices have been the dominant technology. In the latest (Gen III) I2 tube devices, incident photons impinge on a GaAs photocathode and electrons are generated and accelerated toward a microchannel plate (MCP), which amplifies the electrons with gain up to 10000×. The amplified electrons are further accelerated toward the phosphor screen to form the low-light image scene. The superior low light image quality of the I2 tube can be achieved due to extremely low dark current, which is due to a large bandgap of the GaAs photocathode at 1.42 eV (compared to silicon bandgap of 1.12 eV). The extremely low read noise of the I2 tube is due to the high gain provided by the MCP. I2 tubes also can have a fast frame rate, equivalent to 1000 Hz, which is related to P43 phosphor decay time of 1 ms. In the I2 tube, the dark shot noise can be very low due to the use of GaAs material as the photocathode; however, the dominant noise is photon shot noise. I2 tubes tend to be bulky, can require special manufacturing, and can have limited mean time to failure (MTTF).

Image signal-to-noise (SNR) ratio is normally used to quantify the low light image quality. A simplified SNR formula is given in equation 1 below:

$$SNR = \frac{S}{\sqrt{{F}^{2} ( S + {S}_{dark} ) + {( \frac{{n}_{read}}{G} )}^{2}}} . \qquad ( 1 )$$

In equation (1), S is the signal in electrons, Saark is the dark signal in electrons, F is the extra noise factor, n_{read} is the input-referred read noise floor of readout circuitry in electrons, and G is the pixel/sensor gain.

Recently, several digital night vision solutions have been developed to take advantage of standard silicon microelectronics processing techniques. Examples include electron multiplication CCD (EMCCD), single photon avalanche diodes (SPAD), and CMOS sensors. The native read noise of an EMCCD is typically high between 50e− to 100e− input referred. An EMCCD can achieve very low equivalent read noise due to high gain (G>>1), but it suffers from a high dark current and has an excess read noise factor F of about 1.4. To reduce dark current impact, the typical EMCCD operating temperature is set to −40 degree Celsius or lower, which can be impractical for many applications.

A SPAD sensor can achieve true read noise-free operation (G is infinity) but its performance is typically limited by a higher dark count rate (DCR). State of art CMOS pixels can have sub 1e− read noise and acceptable low dark current for many applications. In a CMOS pixel, the F is 1 and G is 1 in equation (1). However, for extreme low light conditions (such as moonless night sky, cloudy overcast night sky), the illumination level can be lower than 0.1 mlux. Under those conditions, only the I2 tube can provide acceptable performance.

Various combinations of analog and digital binning can be used to improve low-light sensitivity, but these methods can also increase dark current and read noise. In analog binning, for example, signals from two or more neighbor pixels may be combined in the charge domain before being sensed by a sensing node. Due to the circuitry involved to support the binning operation, the effective sensing node (i.e., the floating diffusion FD) capacitance can increase, which can cause an increase in read noise. In digital binning, the signals of two or more neighbor pixels may be combined in the digital domain, and the read noise may increase according to the square root of binned pixel count. In both analog and digital binning, the dark current typically increases proportionally to the binned pixel count and increases the dark shot noise contribution.

For sensors with a large pixel sensing region, the corresponding dark current may be higher due to the large silicon device area and an interface with a shallow trench isolation (STI). In addition, for a normal 4T CMOS pixel, the large pixel sensing region tends to have image lag issues due to the large travel distance of collected charge inside the photodiode. Image lag will typically present as a fixed pattern noise (FPN) on the image, which can severely degrade image quality for night vision applications. Despite the recent advances in low-light sensors, there remains a need for improved digital devices with low light performance that can match or exceed an I2 tube.

### BRIEF SUMMARY

The disclosed technology includes a pixel architecture for imaging devices with reduced dark current and improved signal-to-noise ratio. The pixel architecture includes a light-sensing pixel characterized by an optical acceptance aperture having a first dimension D defined by a unit pixel pitch, a sensing region having a second dimension d smaller than the first dimension D of the unit pixel pitch, the sensing region defined within a border of a first full depth deep-trench-isolation (FDTI), and a light concentration structure configured to receive light incident at the optical acceptance aperture and concentrate and direct the received light to the sensing region.

Certain exemplary implementations of the disclosed technology include a night vision device with reduced dark current and an improved signal-to-noise ratio. The night vision device includes an array of light-sensing pixels, each light-sensing pixel of the array is characterized by an optical acceptance aperture having a first dimension D defined by a unit pixel pitch, a sensing region having a second dimension d smaller than the first dimension D of the unit pixel pitch, the sensing region defined within a border of a first full depth deep-trench-isolation (FDTI), and a light concentration structure configured to receive light incident at the optical acceptance aperture and concentrate and direct the received light to the sensing region.

A method of manufacturing an imaging device is disclosed for reducing dark current and improving a signal-to-noise ratio. The method includes forming a pixel array, each pixel of the pixel array manufactured by forming a sensing region having a dimension d on a wafer, forming a full depth deep-trench-isolation (FDTI) to border the sensing region, forming a light concentration structure, and forming a gapless microlens array over the pixel array, each gapless microlens of the gapless microlens array defining an optical acceptance aperture characterized by a dimension D that is greater than d and configured to receive light incident at the optical acceptance aperture and concentrate and direct the received light to the sensing region.

Other implementations, features, and aspects of the disclosed technology are described in detail herein and are considered a part of the claimed disclosed technology. Other implementations, features, and aspects can be understood with reference to the following detailed description, accompanying drawings, and claims.

### BRIEF DESCRIPTION OF THE FIGURES

Reference will now be made to the accompanying figures and flow diagrams, which are not necessarily drawn to scale, and wherein:

FIG. 1 illustrates a light concentrator that utilizes a Fresnel lens to concentrate received light from an aperture having a dimension D to a smaller target having a dimension d, where d<D.

FIG. 2 shows the theoretical upper limit of photon count per pixel using an F#1.4 lens to capture a 0.1 mlux scene illumination over visible and near-infrared wavelengths (400 nm-1100 nm) and captured at 30 frames per second, which corresponds to a 2856K ideal blackbody light source.

FIG. 3A illustrates an example cross-section view of a monochrome backside illumination (BSI) CMOS pixel with a light pipe concentrator having a greatly reduced light sensing region, according to an example implementation of the disclosed technology.

FIG. 3B illustrates an alternative wafer stacking configuration that may utilized with a BSI CMOS pixel (such as the upper portion of the BSI CMOS pixel illustrated in FIG. 3A) which can include a logic carrier wafer bonded together with the sensor wafer using wafer stacking.

FIG. 4 depicts an example top view of a BSI CMOS pixel having an optical pixel size D and a first full-depth deep-trench-isolation (FDTI) enclosing a sensing region having a smaller dimension d. The optical pixel size D may correspond to the pixel pitch for an array of pixels, according to an example implementation of the disclosed technology.

FIG. 5 depicts an example top view of a BSI CMOS pixel having similar features as shown in FIG. 4, plus a second FDTI (of approximate dimension D) bordering the optical pixel, according to an example implementation of the disclosed technology.

FIG. 6 illustrates an example cross-section view of a color backside illumination (BSI) CMOS pixel with a light pipe concentrator having a greatly reduced light sensing region, according to an example implementation of the disclosed technology.

FIG. 7 illustrates an example cross-section view of a color frontside illumination (FSI) CMOS pixel with a light pipe concentrator having a greatly reduced light sensing region, according to an example implementation of the disclosed technology.

FIG. 8 illustrates an example cross-section view of a monochrome backside illumination (BSI) single photon avalanche diode (SPAD) pixel with a light pipe concentrator having a greatly reduced light sensing region, according to an example implementation of the disclosed technology.

FIG. 9 illustrates an example cross-section view of a color backside illumination (BSI) single photon avalanche diode (SPAD) pixel with a light pipe concentrator having a greatly reduced light sensing region, according to an example implementation of the disclosed technology.

FIG. 10 illustrates an example cross-section view of a color backside illumination (BSI) single photon avalanche diode (SPAD) pixel with metal-filled FDTI to reduce pixel-to-pixel crosstalk, a light pipe, and a greatly reduced light sensing region bordered by a smaller FDTI, according to an example implementation of the disclosed technology.

FIG. 11 illustrates an example cross-section view of a color backside illumination (BSI) single photon avalanche diode (SPAD) pixel with an inner micro-lens for light focusing, according to an example implementation of the disclosed technology.

FIG. 12 illustrates an example cross-section view of a color backside illumination (BSI) single photon avalanche diode (SPAD) pixel having a grating structure or binary optical lens to direct incident light to the light pipe, according to an example implementation of the disclosed technology.

FIG. 13 illustrates an example cross-section view of a color backside illumination (BSI) single photon avalanche diode (SPAD) pixel with metal-filled FDTI to reduce pixel-to-pixel crosstalk, a light pipe, and a greatly reduced light sensing region bordered by a smaller FDTI and having a half pitch gapless microlens to direct incident light to the light pipe for further light concentration, according to an example implementation of the disclosed technology.

FIG. 14 is a flow diagram of a method, according to an example implementation of the disclosed technology.

### DETAILED DESCRIPTION

The disclosed technology includes a new pixel architecture that can reduce dark current and can improve signal-to-noise, particularly for low-light sensing applications. Certain exemplary implementations of the disclosed technology utilize a light-sensing pixel having a large optical acceptance aperture characterized by a dimension D approximately equivalent to the pixel pitch (i.e., center-to-center pixel spacing), a light concentration structure, and a pixel sensing area characterized by a smaller sensing region having a dimension d<D (i.e., smaller than the optical acceptance aperture D), which allows for the collection of more photons for reduced dark current and/or read noise. In accordance with certain exemplary implementations, the ratio D/d may be configured as needed. In certain exemplary implementations, the pixel sensing area may be defined within a deep trench isolation boundary having an approximate dimension of d. Certain exemplary implementations of the disclosed technology may also include an additional deep trench isolation boundary having an approximate dimension of D to reduce pixel-to-pixel crosstalk. In certain exemplary implementations, the deep trench isolation boundary may be metal filled.

In accordance with certain exemplary implementations of the disclosed technology, analog binning and/or digital binning may be used to further improve the associated low light sensitivity of the pixel. Additionally, by utilizing light concentration in the new pixel architecture, noise-free “optical binning” may be achieved. Certain exemplary implementations of the disclosed technology may also enable fabrication of the new pixel architecture using standard microelectronic foundry manufacturing processes that utilize silicon substrates, which may provide manufacturing, reliability, and cost-saving advantages over previous devices such as analog image intensification (I2) tubes.

In photon sensing and imaging devices, the image signal-to-noise ratio (SNR) is limited by the total photon count per pixel per frame time. To achieve higher SNR under extremely low light, example implementations of the disclosed technology utilize a large “effective” physical pixel size (defining the incident light acceptance aperture) and a light concentrator structure to concentrate the gathered incident light to impinge on a smaller actual sensing pixel device.

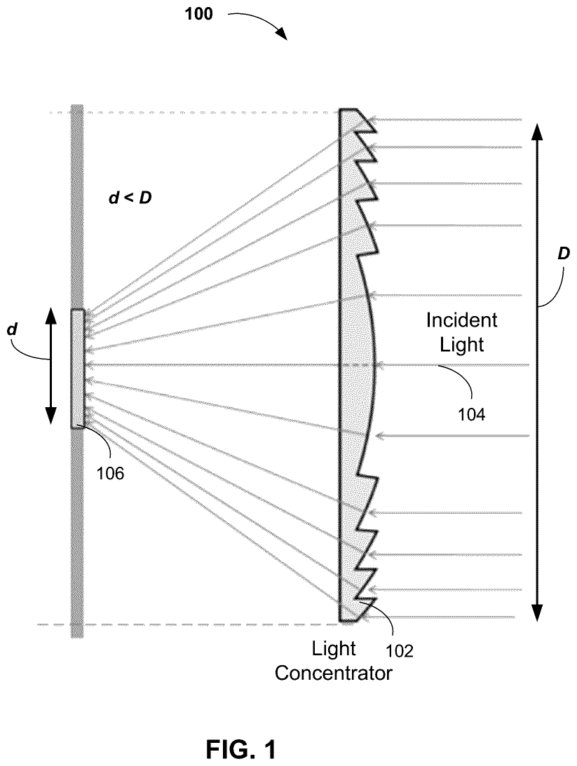

FIG. 1 illustrates the concept of concentrating light. For example, a light concentrator 102 may receive incident light 104 over its aperture dimension D and may concentrate the incident light 104 to a region 106 having a smaller dimension d, thus increasing the illuminance (lumens/m²) incident on the smaller region.

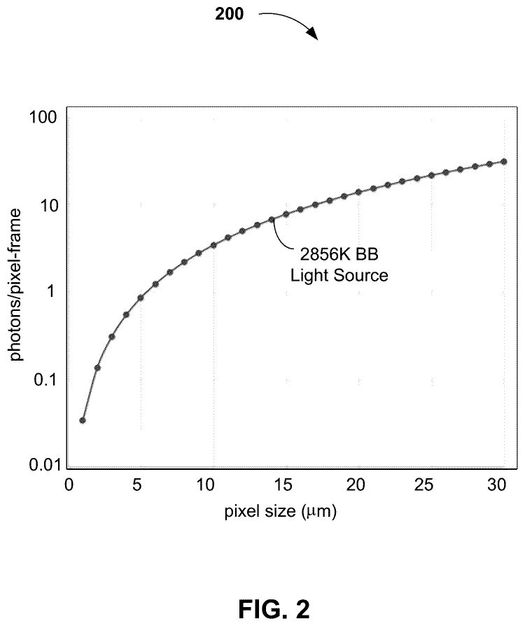

FIG. 2 shows the theoretical upper limit of photon count per pixel using an F#1.4 lens to capture a 0.1 mlux scene illumination over visible and near-infrared wavelengths (400 nm-1100 nm) captured at 30 frames per second, which corresponds to a 2856K blackbody. For a moonless night sky, the corresponding illumination power spectrum is closely matched by an ideal 2856K blackbody, which may be used to compute the photon count. To achieve an SNR of 1, one photon is needed based on equation (1). At 0.1 mlux, the minimum pixel size required is 5.0 μm.

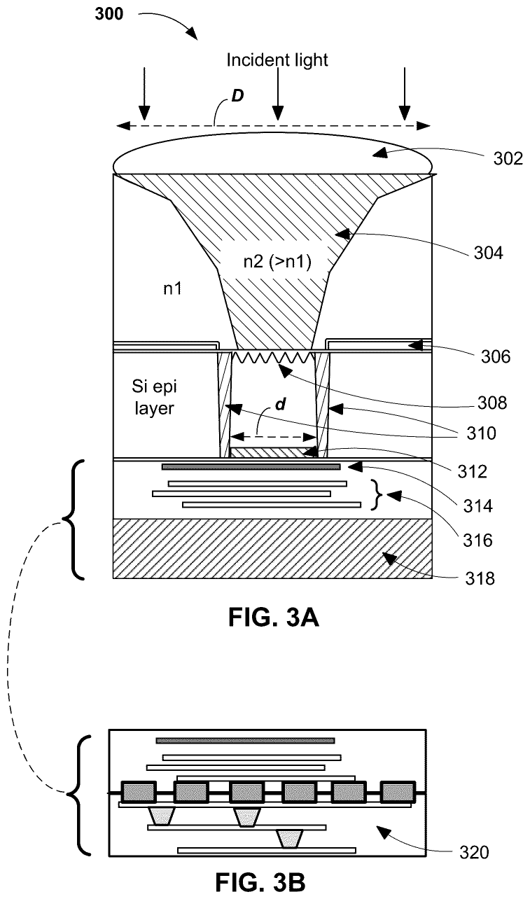

FIG. 3A illustrates an example cross-section view of a monochrome backside illumination (BSI) CMOS pixel 300, in accordance with certain exemplary implementations of the disclosed technology.

FIG. 3B illustrates an alternative wafer stacking configuration that may utilized with a BSI CMOS pixel 300 (such as the upper portion of the BSI CMOS pixel illustrated in FIG. 3A) which may utilize a logic carrier wafer 320 bonded together with the sensor wafer using wafer stacking, for example, to provide additional circuitry or functionality. Certain implementations of the wafer stacking may utilize techniques, materials, etc., as discussed in S.-G. Wuu, H.-L. Chen, H.-C. Chien, P. Enquist, R. M. Guidash and J. McCarten, “A Review of 3-Dimensional Wafer Level Stacked Backside Illuminated CMOS Image Sensor Process Technologies,” in IEEE Transactions on Electron Devices, vol. 69, no. 6, pp. 2766-2778, June 2022, which is incorporated herein by reference as if presented in full. Certain implementations of the wafer stacking may utilize techniques, materials, etc., as discussed in Y. Oike, “Evolution of Image Sensor Architectures With Stacked Device Technologies,” in IEEE Transactions on Electron Devices, vol. 69, no. 6, pp. 2757-2765, June 2022, which is incorporated herein by reference as if presented in full.

Returning to FIG. 3A, the example pixel 300 includes a gapless microlens 302 that can accept incident light over an effective acceptance aperture having a dimension D, and a light pipe 304 concentrator that further concentrates the incident light to a sensing region having a smaller dimension d. In this exemplary embodiment, a photodiode 312 may be utilized to detect concentrated light. In other implementations, which will be discussed below, other detectors such as photoconductors, single photon avalanche diodes (SPADs), etc., may be utilized.

The light pipe 304 concentrator may include an outer region characterized by a first refractive index N1, and a central region characterized by a second refractive index N2>N1 such that light entering the top portion of the light pipe 304 concentrator will be contained within the higher index region (N2) via total internal reflection, similar to the waveguiding properties of an optical fiber. The light pipe 304 concentrator material may be selected to have a very small/minimal absorption for light with wavelength between 300 nm to 1200 nm. In accordance with certain exemplary implementations of the disclosed technology, various profiles, shapes, materials, and manufacturing techniques of the light pipe 304 concentrator may be implemented without departing from the scope of the disclosed technology, as discussed in J. Gambino, et al, “CMOS image sensor with high refractive index lightpipe”, IISW 2009, which is incorporated herein by reference. In accordance with certain exemplary implementations of the disclosed technology, the actual pixel sensing area dimensions, light pipe height, light pipe side-wall profile, gapless microlens curvature, and/or associated material properties may be optimized based on optical simulation, such as via a Finite-Difference Time-Domain (FDTD) method.

As illustrated in FIG. 3A, certain implementations of the disclosed technology utilize a first full-depth deep-trench-isolation (FDTI) 310, for example, to define a smaller device region (having dimension d) and therefore achieving reduced dark current. In certain exemplary implementations, the FDTI 310 may fully extend through a silicon epi-layer of the pixel 300 and may be characterized by a vertical boundary around the detector 310 with an approximate (horizontal internal extent) region characterized by the dimension d.

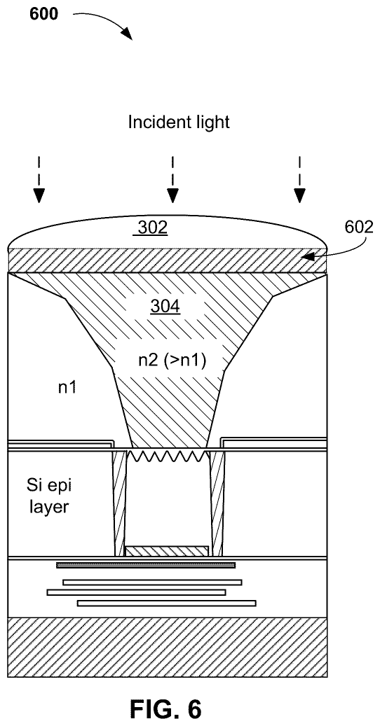

In accordance with certain exemplary implementations of the disclosed technology, the example pixel 300 can include one or more of an optional backside metal shield 306, a textured surface 308, a metal reflector 314, metal routing layers 316, and a carrier wafer 318. In general, an optional backside metal shield 306 can be combined with texture 308 to increase light trapping inside pixel region FDTI 310 to improve NIR light absorption. In certain exemplary implementations, the texture 308 can be on the surface as shown in FIG. 3A or embedded inside the sensing region elsewhere. For example, the texture 308 can be placed above and near the metal reflector 314. In certain exemplary implementations, the texture 308 may be placed along one or more walls of the first FDTI 310. In certain exemplary implementations, the carrier wafer 318 can be dummy bulk wafer (as shown in the lower portion of FIG. 3A) or a logic carrier wafer 320 (as illustrated in FIG. 3B) with logic and/or memory circuitry, for example, to provide additional functionality to enhance the image sensor's performance. In accordance with certain exemplary implementations of the disclosed technology, the logic carrier wafer 320 can be bonded with the pixel wafer via wafer stacking technologies, such as micro-bumps, through silicon vias (TSV), direct Cu-to-Cu hybrid bonding, etc. The above-referenced components illustrated in FIG. 3A and/or FIG. 3B may be the same as, or similar to components as illustrated in the other example implementations as will be discussed below with reference to FIGS. 6-13. One or more of these features or components may be included to improve near-infrared (NIR) light sensitivity, which can be important for many low-light imaging applications. For example, for imaging applications in a moonless night sky, there are more photons in the NIR wavelength range than in the visible light wavelength range. In accordance with certain exemplary implementations of the disclosed technology, the textured surface 308 may be utilized to enhance the near-infrared light (NIR) quantum efficiency (QE). In certain exemplary implementations, the metal reflector 314 may also be utilized to further boost the NIR QE.

For a CMOS pixel, its dark current consists of three components: generation current in the depletion region, diffusion current, and surface generation—each of which is dependent on the pixel dimension. State-of-the-art CMOS pixels can already achieve a very low dark current. However, to further reduce dark current for a large pixel, a reduction in the actual device's sensing region may be the most effective way to reduce the dark current (besides cooling the camera, which is not realistic in most low-light applications).

In addition to the direct benefit of reduced dark current for the smaller pixel sensing area (d), the reduction in the size of the sensing area may also provide the benefit of lower read noise. For example, in a CMOS pixel, input referred read noise is typically determined by the float diffusion (FD) conversion gain in units of “μV/e−” which is the inverse of FD capacitance. Due to a smaller charge transfer gate (TX) and reduced coupling, FD capacitance can be made much smaller for a smaller pixel size than for a large pixel, which can result in a much higher FD conversion gain. By further combining the disclosed technology with other FD technologies, such as distal FD, the FD capacitance can be made even smaller. In addition, for a normal 4T CMOS pixel, the large pixel sensing region tends to have image lag issues due to the large travel distance of collected charge inside the photodiode. Image lag will typically present as a fixed pattern noise (FPN) on the image, which can severely degrade image quality for night vision applications. By using a smaller pixel, charge transfer could be greatly improved and therefore with much reduce FPN noise.

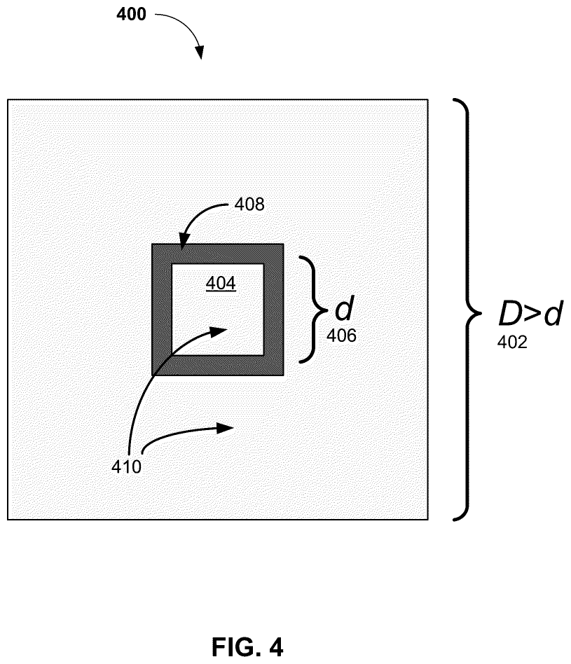

FIG. 4 depicts an example top view of a pixel 400 having an “effective” optical pixel size D 402 and a sensing device 404 characterized by a device pixel size d 404 that is smaller than the optical pixel size D 402. As discussed above, a lens and/or light pipe may “collect” incident light over the optical pixel size D 402 and concentrate the light to a region of size d 404. In accordance with certain exemplary implementations, the ratio D/d may be configured as needed. For example, the ratio D/d may be ≥1.5. In certain exemplary implementations, the ratio D/d may be ≥2. In certain exemplary implementations the ratio D/d may be ≥5. In certain exemplary implementations, the pixel 400 includes a full-depth deep-trench-isolation (FDTI) 408 that borders the sensing device 404. In certain exemplary implementations, the trench may be filled with a polysilicon dielectric. Other dielectric materials may be utilized to fill the FDTI 408 without departing from the scope of the disclosed technology.

In certain exemplary implementations, the optical pixel size D 402 may correspond to the pixel pitch (i.e., center-to-center spacing) for an array of pixels. In accordance with certain exemplary implementations, the regions 410 inside and/or outside the FDTI 408 may be silicon-based. In other exemplary implementations, the regions 410 inside and/or outside the FDTI 408 may be non-silicon-based, for example, made from one or more of InGaAs, InP, Geminium, etc. The sensing device 404 can include a photodiode, a photoconductor, a single photon avalanche diode (SPAD), or any combination thereof. In certain exemplary implementations, the pixel 400 may be a backside illuminated (BSI) device. In other implementations, the pixel 400 may be a frontside illuminated (FSI) device.

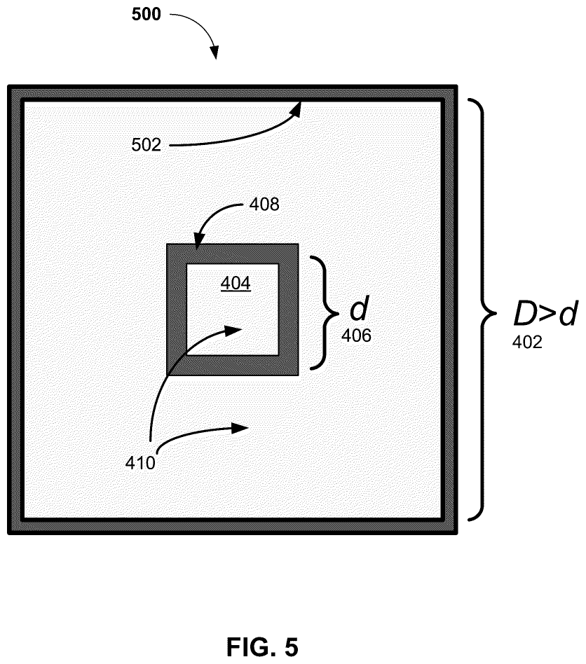

FIG. 5 depicts an example top view of a pixel 500 having similar features as discussed above with reference to FIG. 4, plus a second FDTI 502 bordering the pixel 500. In certain exemplary implementations, the second FDTI 502 may be metal filled. An advantage of the disclosed technology is that it can enable the reduction or complete elimination of optical and/or electrical crosstalk. For example, by virtue of the smaller pixel device region 404 (defined within the first FDTI 408), the distance between neighbor pixel devices region may be increased.

In certain exemplary implementations, the first FDTI 408 and/or the second FDTI 502 may be filled with oxide or air. However, such implementations may not completely block inter-pixel optical crosstalk since light can still penetrate through such isolation trenches. However, in certain implementations, the first FDTI 408 and/or the second FDTI 502 may be filled with a metal (such as Al, Tungsten, Cu, etc.) which can completely block the light. However, the metal fill typically has a negative impact on the dark current if it is near the sensing device 404 region. Accordingly, and in certain implementations, the first FDTI 408 may be filled with air, oxide, polysilicon, etc., and the second FDTI 502 can include the metal fill. In this respect, the second FDTI 502 can be placed far away from the smaller sensing device 404 region, for example, to avoid the negative impact on the dark current, while eliminating inter-pixel crosstalk. In certain exemplary implementations, the region between the first FDTI 408 and the second FDTI 502 may be used to make other circuitry to support/enhance image pixel/sensor performance or functionality. For example, a one-time-programmable-memory (OTPM) cell could be placed in the region between first FDTI 408 and the second FDTI 502 to store defect pixel location information, per-pixel offset to reduce dark signal non-uniformity (DSNU), and/or photon-response non-uniformity (PRNU).

FIG. 6 illustrates an example cross-section view of a color backside illumination (BSI) CMOS pixel 600 (similar to the pixel device 300 discussed above with reference to FIG. 3A) with an added color filter 602, according to an example implementation of the disclosed technology. In certain exemplary implementations, the color filter 602 may be part of a color filter array (CFA). This example embodiment illustrates how the disclosed technology may be used for different wavelength filtering applications, including but not limited to pixels designed for monochrome, color, or hyperspectral applications. In certain exemplary implementations, the color filter 602 can include a dye-based and/or pigment-based material. In certain exemplary implementations, the color filter 602 can include a grating-based and/or nano-structure-based filter. In certain exemplary implementations, the color filter 602 can include a thin-film multi-layer structure. In certain exemplary implementations, the color filter 602 can include a Fabry-Perot-based optical filter.

In accordance with certain exemplary implementations of the disclosed technology, to achieve the best light concentration for different color pixels (such as green, red, blue, or NIR wavelength), the associated lens 302 curvature, height, material, and/or other properties can be optimized individually for each color pixel. In certain exemplary implementations, the light pipe 304 fill material, height, and/or other properties may be optimized individually for each color pixel to achieve the best light concentration result.

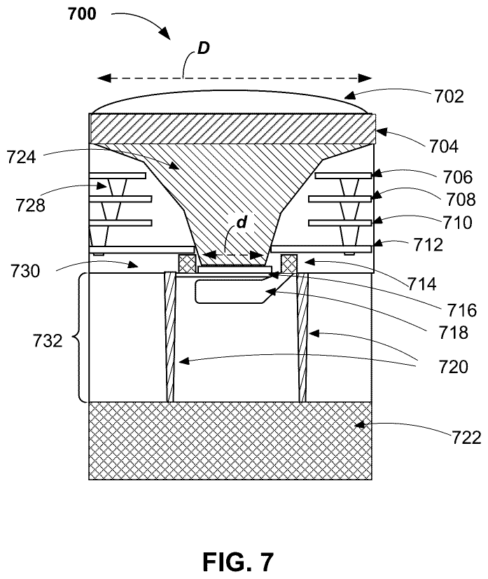

FIG. 7 illustrates an example cross-section view of a color frontside illumination (FSI) CMOS pixel 700, in accordance with certain exemplary implementations of the disclosed technology. As discussed above with regard to the pixel 600 illustrated in FIG. 6 (except for the BSI configuration of the pixel 600) the FSI pixel 700 can include a gapless microlens 702 (which may be part of a lens array), a light pipe 724 concentrator, and/or a color filter 704 (which may be part of a color filter array). The microlens 702 and/or light pipe 724 concentrator may enable collecting light over an acceptance aperture D and concentrating the light to a sensing region d, according to an example implementation of the disclosed technology.

Since the example pixel 700 illustrated in FIG. 7 is designed to be frontside illuminated (in contrast to the backside illuminated designs in the other embodiments discussed herein) the FSI CMOS pixel 700 may include one or more metal layers 706, 708, 710. In certain exemplary implementations, the metal layers 706, 708, 710 can be connected by one or more vias 728. In certain exemplary implementations, one or more metal layers 706, 708, 710 and one or more vias 728 may provide access to the transistors 714, for example, for accessing, resetting, and/or transferring charge from the photodiode to the sensing floating diffusion (FD) node. In certain exemplary implementations, the sensing region d can include a P+ region 716 and an N-well 718, which may form a Pinned photodiode for sensing the concentrated incident light.

In accordance with certain exemplary implementations of the disclosed technology, the example pixel 700 may include deep trench isolation 720, for example, in a silicon epi-layer 732. Certain implementations may include a P++ substrate 722, for example, on the backside of the pixel 700. Certain exemplary implementations of the pixel 700 may include a metal aperture layer 712. Certain exemplary implementations of the pixel 700 can include an anti-reflection coating 730.

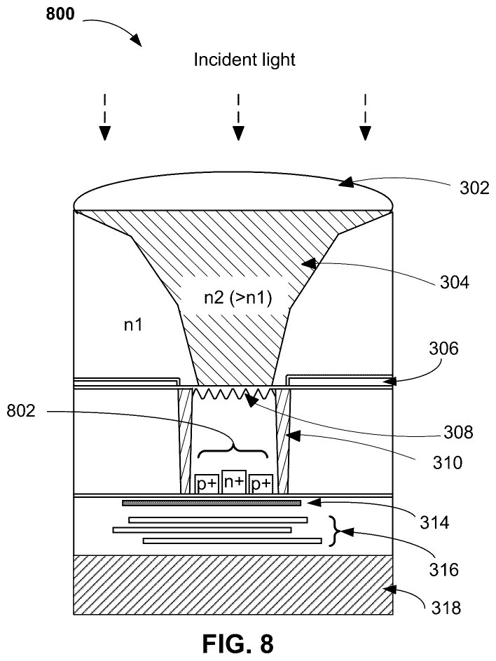

FIG. 8 illustrates an example cross-section view of another monochrome backside illumination (BSI) single photon avalanche diode (SPAD) pixel 800 with a light pipe concentrator having a greatly reduced light sensing region, according to an example implementation of the disclosed technology. The BSI SPAD pixel 800 may include certain similar design features as discussed above with reference to the BSI CMOS pixel 300 shown in FIG. 3A, with the main difference being that the BSI SPAD pixel 800 sensing region can include a SPAD 802. The example pixel 800 can include one or more of a backside metal shield 306, a textured surface 308, a metal reflector 314, metal routing layers 316, and a carrier wafer 318. As discussed above with respect to FIG. 3A and FIG. 3B, the carrier wafer 318 can be a dummy bulk wafer (as shown in the lower portion of FIG. 3A) or a logic carrier wafer 320 (as illustrated in FIG. 3B) with logic and/or memory circuitry, for example, to provide additional functionality to enhance the image sensor's performance. In accordance with certain exemplary implementations of the disclosed technology, the carrier wafer 318 and/or the logic carrier wafer 320 can be bonded with the pixel wafer via wafer stacking technologies, such as micro-bumps, through silicon vias (TSV), direct Cu-to-Cu hybrid bonding, etc.

As previously discussed, the BSI SPAD pixel 800 can include a light concentration structure consisting of gap-less micro-lens 302 and a light pipe. 304. Certain exemplary implementations of the disclosed technology of this SPAD pixel 800 can include embedded texture structure 308 to enhance the NIR QE.

In general, a SPAD pixel may be characterized by a read noise of 0 e−. However, the main drawback of most SPAD pixels is a higher dark count rate (DCR), which is roughly equivalent to the dark current in a CMOS pixel. In a SPAD, the DCR is mainly due to electron avalanche region electric field intensity, avalanche region volume, and/or excess bias voltage. The other dark current factor (such as diffusion current, and surface generation) may also play a role and can be reduced by reducing the pixel device area, as in a CMOS pixel. For a smaller SPAD pixel device region, the avalanche region 802 can be made much smaller, and the excess bias voltage to reach the avalanche condition can be greatly reduced. In accordance with certain exemplary implementations of the disclosed technology, such factors may be utilized to contribute to a much smaller DCR based on the disclosed technology. However, unlike a CMOS pixel, the lowest DCR for a SPAD might not correspond to the smallest pixel size. Based on device optical and electrical simulation, the lowest DCR SPAD pixel may be achieved for a medium pixel size, for example, between about 3 μm to about 6 μm.

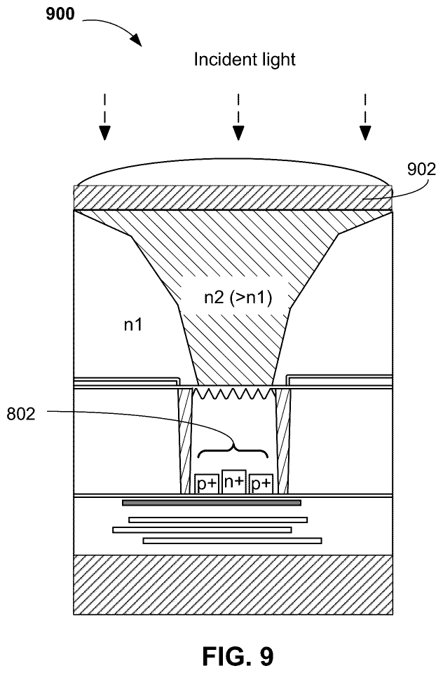

FIG. 9 illustrates an example cross-section view of a color backside illumination (BSI) single photon avalanche diode (SPAD) pixel 900 with a light pipe concentrator having a greatly reduced light sensing region, according to an example implementation of the disclosed technology. The color BSI SPAD pixel 900 may include certain similar design features as discussed above with reference to the monochrome BSI CMOS pixel 800 discussed above in FIG. 8, with the main difference being that the color BSI SPAD pixel 900 can include a color filter 902, which in certain implementations, may be part of an array. While the color BSI SPAD pixel 900 is shown in FIG. 9, certain implementations of the disclosed technology may also be utilized to make an FSI SPAD pixel with much reduced DCR, similar to the FSI CMOS pixel 700 discussed above with reference to FIG. 7, in which the sensing region d may utilize a SPAD.

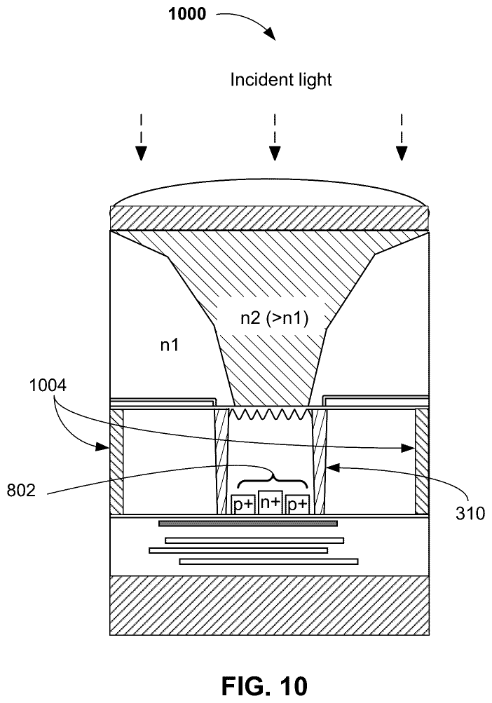

FIG. 10 illustrates an example cross-section view of a color backside illumination (BSI) single photon avalanche diode (SPAD) pixel 1000 with metal-filled (second) FDTI 1004 to reduce or completely eliminate pixel-to-pixel crosstalk, according to an example implementation of the disclosed technology. As in the other examples discussed above, the color BSI SPAD pixel 1000 can include the metal-filled (second) FDTI 1004, a light pipe, and a greatly reduced light sensing region SPAD 802 bordered by a smaller first FDTI 310.

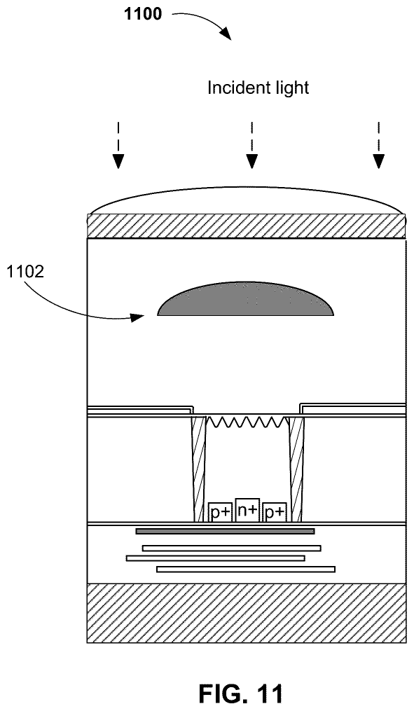

FIG. 11 illustrates an example cross-section view of a color backside illumination (BSI) single photon avalanche diode (SPAD) pixel 1100 with an inner micro-lens 1102 for light focusing, according to an example implementation of the disclosed technology.

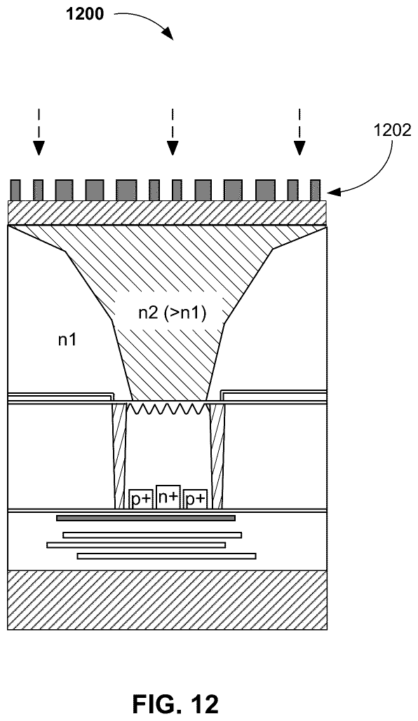

FIG. 12 illustrates an example cross-section view of a color backside illumination (BSI) single photon avalanche diode (SPAD) pixel 1200 having a grating/metalens/nanostructure 1202 to direct incident light to the light pipe, according to an example implementation of the disclosed technology. In this example, the lens 1202 may be fabricated with 1-D grating, 2-D grating, nanocolumns/pillars, metalens, or other structures. In certain exemplary implementations, lens 1202 can be fine-tuned for the desired wavelength range for each color pixel. In certain exemplary implementations, this same type of (non-conventional) lens structure 1202 may be utilized for any of the embodiments discussed herein.

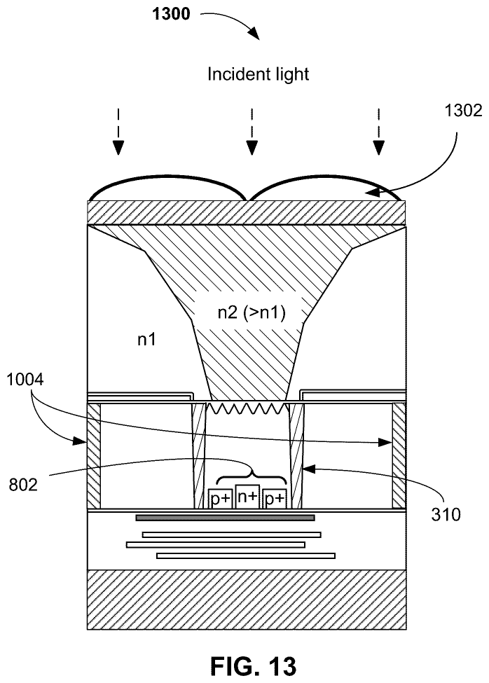

FIG. 13 illustrates an example cross-section view of a color backside illumination (BSI) single photon avalanche diode (SPAD) pixel 1300 having a half-pitch gapless microlens 1302 to direct incident light to the light pipe for further light concentration, according to an example implementation of the disclosed technology. As in the other examples discussed above, the color BSI SPAD pixel 1300 can include the metal-filled (second) FDTI 1004, a light pipe, and a greatly reduced light sensing region SPAD 802 bordered by a smaller first FDTI 310. In accordance with certain exemplary implementations of the disclosed technology, reducing microlens 1302 size to half of the unit pixel size, the focusing efficiency may be improved. This color BSI SPAD pixel 1300 is also shown as having a metal-filled FDTI to reduce pixel-to-pixel crosstalk, a light pipe, and a greatly reduced light sensing region bordered by a smaller FDTI 310.

While SPAD-based BSI pixels are illustrated in FIGS. 8-13, the disclosed technology may also be utilized for FSI SPAD pixels with reduced DCR. For example, rather than utilizing a photodiode-based detector in the sensing region d in FIG. 7, a SPAD structure (similar to the SPAD 802 shown in FIG. 8) may be utilized.

It should be recognized that any of the embodiments disclosed herein may utilize the second metal-filled FDTI (such as the FDTI 502 discussed with reference to FIG. 5, or the FTDI 1004 as discussed with reference to FIG. 10), for example, to reduce or completely eliminate pixel cross-talk.

It should be recognized that any of the embodiments disclosed herein may utilize the top gap-less microlens and embedded inner micro-lens (such as the micro-lens 1102 as discussed above with reference to FIG. 11.

It should be further recognized that any of the embodiments disclosed herein may utilize a non-conventional lens (such as the lens 1202 discussed above in reference to FIG. 12), which can be fabricated as a 1-D grating, 2-D grating, nanocolumns, nanopillars, a metalens, a binary optics lens, a Fresnel lens, and/or other structures. In accordance with certain exemplary implementations of the disclosed technology, the non-conventional lens structure may be designed for a particular wavelength range for each color pixel.

It should be further recognized that any of the embodiments disclosed herein may utilize a half (or smaller) pitch gap-less microlens and light pipe. By reducing the microlens size to half of the unit pixel size, the focusing efficiency may be improved.

It should be further recognized that any of the embodiments disclosed herein can be applied to a CMOS pixel or a SPAD pixel made via wafer stacking technology (2 wafers, 3 wafers, or more) or a charge-coupled device (CCD) pixel. Thus, the disclosed technology may be applicable in FSI and/or BSI applications that utilize wafer stacking. For example, wafer bonding and stacking technology may be utilized to bond wafers to add additional functionality.

Certain implementations of the disclosed technology may be applied to other pixel designs or other non-silicon-based materials for use with different wavelength ranges and may be particularly beneficial in pixel devices in which the device's dark current is strongly dependent on pixel dimensions. The use of the light concentrations (i.e., optical binning) and focusing the gathered photons into a much-reduced device region, as discussed herein, may improve the device's performance.

It should be recognized that other pixel materials may be utilized without departing from the scope of the disclosed technology. For example, certain implementations of the disclosed technology may employ pixels having materials such as germanium, micro-bolometer, III-V material (such as GaAs, InGaAs) for SWIR, MWIR, LWIR, and/or VLWIR applications. The light concentration structures that can be made compatible with such different materials, and can include micro-lens, a grating, a nanostructure, metalens, a light pipe, an inner embedded micro-lens, etc.

The technical advantages of the disclosed technology can include one or more of: a reduced pixel dark current, a reduced pixel crosstalk, a reduced read noise for CMOS pixel, a reduced pixel lag, a reduced excess bias voltage for SPAD pixel, a reduced DCR for SPAD pixel, and/or an increased low light image SNR.

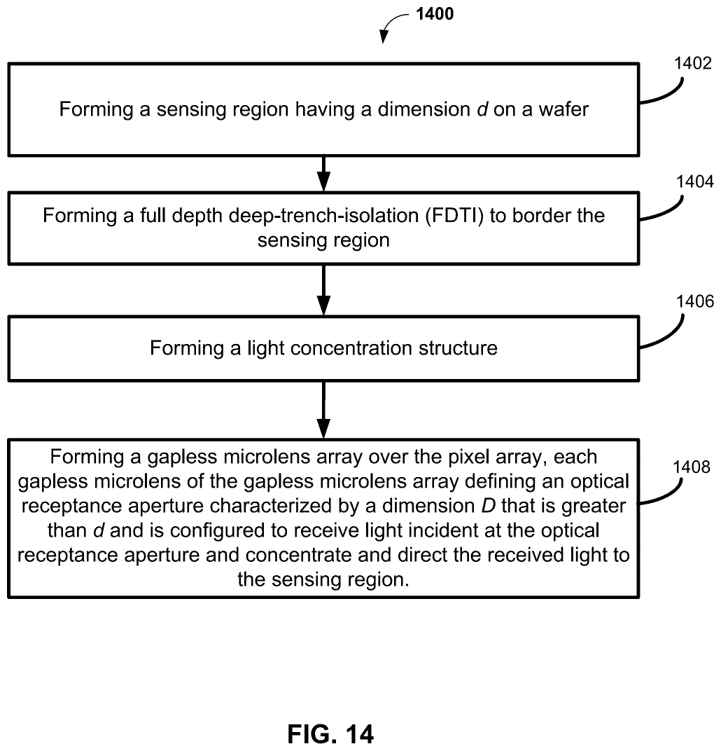

FIG. 14 is a flow diagram of a method 1400 of manufacturing an imaging device having reduced dark current and improved signal-to-noise ratio by forming a pixel array, wherein one or more of each pixel of the pixel array may be manufactured by the method 1400 according to an example implementation of the disclosed technology. In block 1402, the method 1400 includes, forming a sensing region having a dimension d on a wafer. In block 1404, the method 1400 includes forming a full-depth deep-trench-isolation (FDTI) to border the sensing region. In block 1406, the method 1400 includes forming a light concentration structure. In block 1408, the method 1400 includes forming a gapless microlens array over the pixel array, each gapless microlens of the gapless microlens array defining an optical acceptance aperture characterized by a dimension D that is greater than d and configured to receive light incident at the optical acceptance aperture and concentrate and direct the received light to the sensing region.

In accordance with certain exemplary implementations of the disclosed technology, forming the gapless microlens array over the pixel array can include forming a microlens array structure using photolithography and further applying material reflow or material etching to the microlens array structure.

In certain exemplary implementations, forming the light concentration structure can include forming a light pipe waveguide, a gapless microlens, an inner microlens; and/or a binary optical lens.

In accordance with certain exemplary implementations of the disclosed technology, forming the sensing region can include forming an embedded texture on a silicon surface of the sensing region and/or a metal reflector structure.

As discussed herein, the disclosed technology may utilize an embedded texture on the Si surface to enhance the near-infrared light (NIR) quantum efficiency (QE) and a metal reflector structure to further boost the NIR QE.

Certain exemplary implementations of the disclosed technology may be utilized to fabricate a pixel with reduced read noise. Since input-referred read noise may be a function of float diffusion (FD) conversion gain, which is inversely proportional to FD capacitance, the input-referred read noise may be reduced by combining FD technologies (such as distal FD) with the disclosed technology to enable a smaller pixel size.

As disclosed herein, ratio D/d may be configured, for example, by adjusting design parameters. For example, the ratio D/d may be ≥1.5. In certain exemplary implementations, the ratio D/d may be ≥2. In certain exemplary implementations the ratio D/d may be ≥5. In accordance with certain implementations, this ratio may be configured as needed by specifying one or more of (a) the sensing region dimension d; (b) the light concentration structure (including geometry and materials); and/or (c) the microlens design.

In certain exemplary implementations, an improved signal-to-noise ratio may be achieved through lower read noise resulting from a smaller charge transfer gate (TX) and reduced coupling, and further reduction of the float diffusion (FD) capacitance through FD technologies such as distal FD.

In certain exemplary implementations, an improved signal-to-noise ratio may be achieved through reduced pixel crosstalk, both optical and electrical, and/or through an increase in the distance between neighboring pixel device regions.

Certain exemplary implementations of the disclosed technology may be utilized to produce BSI and or FSI pixels having reduced pixel crosstalk, both optical and electrical, due to increased distance between neighbor pixel device regions and by virtue of the smaller pixel device sensing region defined by its bordering FDTI.

Certain aspects of the disclosed technology can provide digital images that match or exceed images (in low light conditions) that can only be created by image intensifier systems. As described herein, certain aspects of the disclosed technology provide an imaging array arranged to convert detected photons into a digital image.

As noted above, systems and methods described herein can in, some aspects, provide processing of devices at the wafer level. For example, such a wafer may comprise a plurality of pixel devices described herein. Relative to conventional image intensifier manufacturing techniques that produce a single image intensifier at a time, many pixel devices in accordance with various aspects of the disclosed technology may be produced on a single wafer, thereby increasing throughput and/or decreasing the cost per device due to the parallel processing.

In various aspects, a wafer may comprise a “sensing” array subcomponent comprising a plurality of photodiodes, SPADs, etc., each with its respective light concentrators. In certain exemplary implementations, the disclosed technology can include aligning an array of microlenses with the plurality of photodiodes/SPADS.

Numerous characteristics and advantages have been set forth in the foregoing description, together with details of structure and function. While the disclosed technology has been disclosed in several forms, it will be apparent to those skilled in the art that many modifications, additions, and deletions, especially in matters of shape, size, and arrangement of parts, can be made therein without departing from the spirit and scope of the disclosed technology and its equivalents as set forth in the following claims, which encompass various alternatives, modifications, and equivalents, as will be appreciated by those of skill in the art.

What is claimed is:

1. A pixel architecture for imaging devices with reduced dark current and improved signal-to-noise ratio, the pixel architecture comprising:
a light-sensing pixel characterized by:
an optical acceptance aperture having a first dimension D defined by a unit pixel pitch;
a sensing region having a second dimension d smaller than the first dimension D of the unit pixel pitch, the sensing region defined within a border of a first full depth deep-trench-isolation (FDTI); and
a light concentration structure configured to receive light incident at the optical acceptance aperture and concentrate and direct the received light to the sensing region.

2. The pixel architecture of claim 1, wherein the light-sensing pixel is a backside illuminated (BSI) CMOS pixel or a frontside illuminated (FSI) CMOS pixel.

3. The pixel architecture of claim 1, wherein the light concentration structure comprises a light pipe waveguide.

4. The pixel architecture of claim 1, wherein the light concentration structure comprises one or more of a binary optical lens and a grating-based lens.

5. The pixel architecture of claim 1, wherein the light concentration structure comprises one or more of a gapless microlens and an inner microlens.

6. The pixel architecture of claim 1, wherein the sensing region comprises a photodiode, a photoconductor, a single photon avalanche diode (SPAD), or a non-silicon-based detector made from one or more of InGaAs, InP, and Germanium.

7. The pixel architecture of claim 1, further comprising a second FDTI having a dimension substantially equivalent to D and surrounding the first FDTI.

8. The pixel architecture of claim 7, wherein the second FDTI is filled to reduce or eliminate pixel crosstalk.

9. The pixel architecture of claim 1, further comprising an embedded texture on a silicon surface or embedded inside the sensing region.

10. The pixel architecture of claim 1, further comprising a metal reflector structure.

11. The pixel architecture of claim 1, further comprising a color filter.

12. The pixel architecture of claim 1, wherein the ratio D/d is greater than or equal to 1.5.

13. The pixel architecture of claim 1, wherein the ratio D/d is greater than or equal to 2.0.

14. The pixel architecture of claim 1, wherein the ratio D/d is greater than or equal to 5.0.

15. A night vision device with reduced dark current and improved signal-to-noise ratio, the night vision device comprising:
an array of light-sensing pixels, each light-sensing pixel of the array is characterized by:
an optical acceptance aperture having a first dimension D defined by a unit pixel pitch;
a sensing region having a second dimension d smaller than the first dimension D of the unit pixel pitch, the sensing region defined within a border of a first full depth deep-trench-isolation (FDTI); and
a light concentration structure configured to receive light incident at the optical acceptance aperture and concentrate and direct the received light to the sensing region.

16. The night vision device of claim 15, wherein each light-sensing pixel of the array is a backside illuminated (BSI) CMOS pixel or a frontside illuminated (FSI) CMOS pixel.

17. The night vision device of claim 15, wherein the light concentration structure comprises one or more of:
a light pipe waveguide;
a gapless microlens;
an inner microlens; and
a binary optical lens.

18. The night vision device of claim 15, wherein each light-sensing pixel of the array comprises a second FDTI having a dimension substantially equivalent to D and surrounding the first FDTI, wherein the second FDTI is metal filled to reduce or eliminate pixel crosstalk.

19. The night vision device of claim 15, wherein each light-sensing pixel of the array comprises one or more of:
an embedded texture on a silicon surface of the sensing region;
a metal reflector structure; and
a color filter.

20. The night vision device of claim 15, wherein the ratio D/d is greater than or equal to 1.5.

21. A method of manufacturing an imaging device having reduced dark current and improved signal-to-noise ratio, comprising:
forming a pixel array, each pixel of the pixel array is manufactured by:
forming a sensing region having a dimension d on a wafer;
forming a full-depth deep-trench-isolation (FDTI) to border the sensing region;
forming a light concentration structure; and
forming a gapless microlens array over the pixel array, each gapless microlens of the gapless microlens array defining an optical acceptance aperture characterized by a dimension D that is greater than d and configured to receive light incident at the optical acceptance aperture and concentrate and direct the received light to the sensing region.

22. The method of claim 21, wherein forming a gapless microlens array over the pixel array comprises forming a microlens array structure using photolithography and further applying material reflow or material etching to the microlens array structure.

23. The method of claim 21, wherein forming the light concentration structure comprises forming one or more of:
a light pipe waveguide;
a gapless microlens;
an inner microlens; and
a binary optical lens.

24. The method of claim 21, wherein forming the sensing region comprises forming one or more of:
an embedded texture on a silicon surface of the sensing region; and
a metal reflector structure.
